(19) United States
(12) Patent Application Publication
(10) Pub. No.: US 2025/0379184 A1
(43) Pub. Date: Dec. 11, 2025

(54) SELF-ALIGNMENT FOR BONDING OF SEMICONDUCTOR DEVICES

(71) Applicant: Yield Engineering Systems, Inc., Fremont, CA (US)

(72) Inventors: Saket Chadda, Freemont, CA (US); Ramakanth Alapati, Dallas, TX (US); M Ziaul Karim, San Jose, CA (US); Nirmalya Maity, Los Altos, CA (US); Rajeev Bajaj, San Jose, CA (US)

(73) Assignee: Yield Engineering Systems, Inc., Fremont, CA (US)

(21) Appl. No.: 19/208,909

(22) Filed: May 15, 2025

Related U.S. Application Data
(60) Provisional application No. 63/647,924, filed on May 15, 2024.
(60) Provisional application No. 63/708,385, filed on Oct. 17, 2024.

(51) Int. Cl. H01L 23/00

(52) U.S. Cl. CPC H01L 24/81; H01L 24/13; H01L 2224/13109; H01L 2224/13111; H01L 2224/13113; H01L 2224/13116; H01L 2224/13147; H01L 2224/81139; H01L 2224/81815; H01L 2224/81896; H01L 2224/81951

(57) ABSTRACT

A method of bonding semiconductor devices utilizing self-alignment. A pair of device features metallic bumps that protrude through their respective dielectric layers, exposing the end surfaces of the bumps. Solder is applied to these exposed surfaces, and the devices are aligned so that the solder on the first device comes into contact with the solder on the second device. During reflow, surface tension forces of the molten solder self-aligns the devices. After reflow, exposed surfaces of the dielectric layers of the two devices are bonded together.

### CROSS-REFERENCE TO RELATED APPLICATIONS

This application claims priority to U.S. Provisional Application No. 63/647,924, filed May 15, 2024, and U.S. Provisional Application No. 63/708,385, filed Oct. 17, 2024, the disclosures of which are incorporated by reference in their entireties herein.

### TECHNICAL FIELD

The present disclosure relates to self-alignment during bonding of semiconductor devices.

### BACKGROUND

Bonding semiconductor devices involves establishing electrical and mechanical connections between components, such as chips and substrates, through methods like wire bonding, flip-chip bonding, or other bonding techniques. However, as the pitch—the spacing between connections between the components—decrease to accommodate higher-density designs, several challenges emerge. Precise alignment becomes increasingly difficult due to the narrower margins for error, requiring advanced equipment and methodologies to maintain accuracy. The reduced pitch also increases the risk of defects such as shorts and open circuits requiring defect mitigation strategies. To overcome these hurdles, continuous advancements in bonding technologies are vital for scaling semiconductor devices to lower pitches effectively.

To achieve higher interconnect densities, the size (e.g., diameter) and pitch (the distance between adjacent bumps) of interconnects decrease progressively with advancing technology generations. For example, standard controlled collapse chip connection (C4) bumps typically have a diameter of 100 microns and a pitch of 150-200 microns. Fine-pitch C4 bumps feature a reduced diameter of 50 microns and a pitch of approximately 100 microns, while micro C4 bumps have diameters ranging from 20-30 microns and a pitch of 30-60 microns. For dimensions below these ranges, copper bumps are employed. Copper pillar bumps, for instance, have diameters of around 15-20 microns and a pitch of 20-30 microns, whereas flat copper bumps are about 10 microns in diameter with a pitch of approximately 20 microns. Bump-less interconnects are utilized for even smaller dimensions, such as 5-micron sizes and a pitch of about 10 microns. The methods and processes described in this disclosure are particularly well-suited for bonding devices with interconnect sizes smaller than 20 microns and a pitch under 30 microns.

“Hybrid bonding” is a relatively new bonding technique that may be used with lower pitch devices. This process involves directly bonding the dielectric layers and metal pads of one semiconductor device to corresponding regions (e.g., dielectric and metal) on another device. The direct connections formed through hybrid bonding result in reliable, low-resistance inter-device linkages. Compared to wire bonding and flip-chip or C4 bonding, hybrid bonding significantly increases interconnect density.

Despite its advantages, hybrid bonding presents implementation challenges, as it requires advanced manufacturing processes and equipment capable of achieving precise alignment and bonding at extremely small dimensions. These demands lead to higher costs and manufacturing difficulties, particularly in high-volume production environments. The systems and methods described in the present disclosure may mitigate some of these limitations.

### SUMMARY

Several embodiments of apparatus, systems, and methods for bonding are disclosed. It is to be understood that both the foregoing general description and the following detailed description are exemplary and explanatory only. As such, the scope of the disclosure is not limited solely to the disclosed embodiments. Instead, it is intended to cover such alternatives, modifications and equivalents within the spirit and scope of the disclosed embodiments. Persons skilled in the art would understand how various changes, substitutions and alterations can be made to the disclosed embodiments without departing from the spirit and scope of the disclosure.

In one embodiment, a method of bonding semiconductor devices is disclosed. The method includes providing a first device having a first surface and a plurality of first metallic bumps extending from the first surface. A first dielectric layer is disposed on the first surface such that the plurality of first metallic bumps extend through the first dielectric layer to expose end surfaces of the plurality of first metallic bumps. The method also includes providing a second device having a second surface and a plurality of second metallic bumps extending from the second surface. A second dielectric layer is disposed on the second surface such that the plurality of second metallic bumps extend through the second dielectric layer to expose end surfaces of the plurality of second metallic bumps. The method may further include applying a solder material on the end surfaces of the plurality of first metallic bumps and the plurality of second metallic bumps, and aligning the first device with the second device such that a first bonding surface of the first dielectric layer faces a second bonding surface of the second dielectric layer and at least portions of the solder material on the end surfaces of the plurality of first metallic bumps contact the solder material on the end surfaces of the plurality of second metallic bumps. The method may also include, after the aligning, heating the first and second devices to reflow the solder material and join the end surfaces of the plurality of first metallic bumps to the end surfaces of the plurality of second metallic bumps using the reflowed solder material, and after the heating, bonding the first bonding surface of the first dielectric layer to the second bonding surface of the second dielectric layer.

Bonding the first bonding surface of the first dielectric layer to the second bonding surface of the second dielectric layer may be through a low-temperature anneal process. This process may fuse the first dielectric layer to the second dielectric layer by maintaining the first and second devices at a temperature between approximately 100-200° C. for a defined time period exceeding zero. The annealing may also involve a high-temperature process to fuse each metallic bump of the first set of metallic bumps to a corresponding bump in the second set. This high-temperature anneal may involve holding the devices at a temperature higher than the initial anneal temperature, for a time period that may be either equal to or different from the time period of the low-temperature anneal.

Additionally, or alternatively, bonding the first bonding surface to the second bonding surface may be using an underfill material that fills the gap between the layers, thereby connecting the first dielectric layer to the second dielectric layer. This underfill material may consist of a polymer brush, and the gap between the bonding surfaces may be less than approximately 5 microns. The solder material that is applied to the end surfaces of the bumps may have a phase transition temperature below 200° C. or below 150° C. Among other choices, the solder materials may include indium solder, lead-tin solder, bismuth-tin solder, and indium-tin solder. The solder material is applied only to the end surfaces of the bumps, excluding the dielectric layers. In some cases, the method may include activation of the devices prior to alignment, involving plasma treatment. In some cases, a horizontal offset between each bump of the first set and its corresponding bump in the second set, may be limited to half the diameter of either bump. In some embodiments, the diameter of each bump may be less than or equal to 20 microns, with a pitch of less than or equal to 30 microns.

In another embodiment, a method of bonding semiconductor devices is disclosed. The method may include providing a first device having a first surface and a plurality of first copper bumps extending from the first surface. A first dielectric layer may be disposed on the first surface such that the plurality of first copper bumps extend through the first dielectric layer and project outwards from a first bonding surface of the first dielectric layer to expose end surfaces of the plurality of first copper bumps. The method may also include providing a second device having a second surface and a plurality of second copper bumps extending from the second surface. A second dielectric layer may be disposed on the second surface such that the plurality of second copper bumps extend through the second dielectric layer and project outwards from a second bonding surface of the second dielectric layer to expose end surfaces of the plurality of second copper bumps. The method may further include applying a solder material on the end surfaces of the plurality of first copper bumps and the plurality of second copper bumps. The solder material may be an electrically conductive material having a phase transition temperature less than or equal to about 200° C. The method may further include aligning the first device with the second device such that at least portions of the solder material on the end surfaces of the plurality of first copper bumps contact the solder material on the end surfaces of the plurality of second copper bumps. After the aligning, the solder material may be reflowed to join the end surfaces of the plurality of first copper bumps to the end surfaces of the plurality of second copper bumps. After the reflowing, the first bonding surface of the first dielectric layer may be bonded to the second bonding surface of the second dielectric layer.

In a further embodiment, a method of bonding semiconductor devices is disclosed. The method includes providing a first device having a first surface and a plurality of first metallic bumps extending from the first surface. A first dielectric layer is disposed on the first surface such that the plurality of first metallic bumps may extend through the first dielectric layer to expose end surfaces of the plurality of first metallic bumps. The method also includes providing a second device having a second surface and a plurality of second metallic bumps extending from the second surface. A second dielectric layer is disposed on the second surface such that the plurality of second metallic bumps may extend through the second dielectric layer to expose end surfaces of the plurality of second metallic bumps. The method may further include applying one or more self-assembled monolayers or one or more layers of polymer brushes on a first surface of the first dielectric layer and a second surface of the second dielectric layer, and aligning the first device with the second device to contact the one or more self-assembled monolayers or one or more layers of polymer brushes on the first surface of the first dielectric layer to the one or more self-assembled monolayers or one or more layers of polymer brushes on the second surface of the second dielectric layer such that at least a portion the end surface of a first bump of the plurality of first metallic bumps overlies the end surface of a second bump of the plurality of second metallic bumps. The method may additionally include after the aligning, annealing the first and second devices to join the first dielectric layer to the second dielectric layer and join each bump of the plurality of first metallic bumps to a different bump of the plurality of second metallic bumps.

### BRIEF DESCRIPTION OF THE DRAWINGS

The drawings provided as part of this disclosure offer simplified schematic representations of exemplary embodiments. These figures, together with the accompanying description, serve to illustrate and explain the principles of the disclosure. Where applicable, reference numerals are used consistently across different figures to indicate similar structures, components, materials, and elements. It is important to note that the figures are simplified schematics of exemplary embodiments, and many features or variations may not be depicted. Various combinations of structures, components, and elements—beyond those shown explicitly—are considered and fall within the scope of the present disclosure. The scope, however, is defined by the claims, not by the specific embodiments shown in the figures.

For the sake of simplicity and clarity, the figures illustrate the general structure of the described embodiments. Well-known components or features may be omitted to avoid overshadowing other aspects, as these omitted elements are familiar to individuals skilled in the art. Additionally, the figures are not drawn to scale; certain dimensions may be exaggerated relative to others to enhance comprehension of the exemplary embodiments. A person of ordinary skill in the art would understand that the depicted features are not proportionally scaled and should not interpret them as indicating exact dimensional relationships unless explicitly stated. Furthermore, aspects described in connection with one embodiment or figure can also apply to and be utilized with other embodiments or figures, even if not explicitly mentioned.

FIGS. 1A-1C are schematic illustrations of an exemplary hybrid bonding process, consistent with the current disclosure;

FIG. 2A-2C are schematic illustrations of an exemplary hybrid bonding process utilizing self-alignment, consistent with the current disclosure;

FIGS. 3A-3D are schematic illustrations of an exemplary underfilling process using a polymer brush technique, consistent with the current disclosure;

FIG. 4 is a flow chart of an exemplary hybrid bonding process utilizing self-alignment, consistent with the current disclosure;

FIG. 5A-5C are schematic illustrations of another exemplary hybrid bonding process utilizing self-alignment, consistent with the current disclosure;

FIG. 6 is a flow chart of another exemplary hybrid bonding process utilizing self-alignment, consistent with the current disclosure;

FIGS. 7A-7C are schematic illustrations depicting different alignment and misalignment between die bumps and dielectrics;

FIGS. 8A-8D are schematic illustrations depicting different offsets between die bumps during rough alignment; and

FIG. 9 is a schematic illustration of a modular activation system consistent with the current disclosure.

### DETAILED DESCRIPTION

All relative terms such as “about,” “substantially,” “approximately,” etc., indicate a possible variation of ±10% (unless noted otherwise or another variation is specified). For example, a feature disclosed as being about “l” units long (wide, thick, etc.) may vary in length from (l-0.1 l) to (l+0.1 l) units. Similarly, a temperature within a range of about 100-150° C. can be any temperature between (100-10%) and (150+10%). Further, a range described as varying from (or between) 100-150, includes the endpoints (i.e., 100 and 150). In some cases, the specification provides context to the relative terms used. For example, substantially linear refers to a relationship or trend that closely follows a straight line, but may exhibit minor deviations from perfect linearity due to practical constraints or real-world limitations. These deviations can arise from factors such as measurement inaccuracies, inherent variability in the system, or external influences that cause slight fluctuations. In many cases, the variation is so small that it does not significantly impact the overall behavior or outcome, but it acknowledges that perfect linearity is difficult to achieve in practice. Thus, in this disclosure, relative terms are used to allow for some degree of variation resulting from practical, real-world, reasons. For example, a substantially linear geometry allows for some degree of non-linearity while still maintaining a general straight-line trend.

As used herein, unless specifically stated otherwise, the term “or” encompasses all possible combinations, except where infeasible. For example, if it is stated that a component (method, etc.) can comprise A or B, then, unless specifically stated otherwise or infeasible, the component can comprise A, or B, or A and B. As a second example, if it is stated that a component can comprise A, B, or C, then, unless specifically stated otherwise or infeasible, the component can comprise A, or B, or C, or A and B, or A and C, or B and C, or A and B and C.

In this disclosure, the term “device” broadly refers to any component or assembly involved in the fabrication, integration, or packaging of electronic circuits and systems. This includes a wide range of elements, such as dies, wafers, and substrates, each serving specific roles in the manufacturing process. A die is a single piece of semiconductor material that contains electronic circuits, which may be fully finished or still undergoing fabrication. A wafer is a thin slice of semiconductor material, typically silicon, that serves as the foundation for one or multiple dies during production. Fully finished IC dies are ready for packaging or integration into systems, while partly finished IC dies are in intermediate stages of fabrication with incomplete circuit structures. Additionally, “devices” such as ceramic substrates and organic substrates provide the structural base for semiconductor devices, offering unique properties like thermal conductivity, electrical insulation, or flexibility. Lastly, “devices” such as printed circuit boards (PCBs) act as platforms to mechanically support and electrically connect semiconductor devices and other components. Bonding two devices by hybrid bonding can therefore refer to bonding a die to another die, a wafer to another wafer, a die to a wafer, die to a substrate, substrate to a substrate, etc.

Unless otherwise defined, all terms of art, notations, and other scientific terms or terminology used herein have the same meaning as is commonly understood by one of ordinary skill in the art to which this disclosure belongs. Some of the components, structures, and/or processes described or referenced herein are well understood and commonly employed using conventional methodology by those skilled in the art. Therefore, these components, structures, and processes will not be described in detail. All patents, applications, published applications and other publications referred to herein as being incorporated by reference are incorporated by reference in their entirety. If a definition or description set forth in this disclosure is contrary to, or otherwise inconsistent with, a definition and/or description in these references, the definition and/or description set forth in this disclosure controls over those in the references that are incorporated by reference. None of the references described or referenced herein is admitted as prior art to the current disclosure.

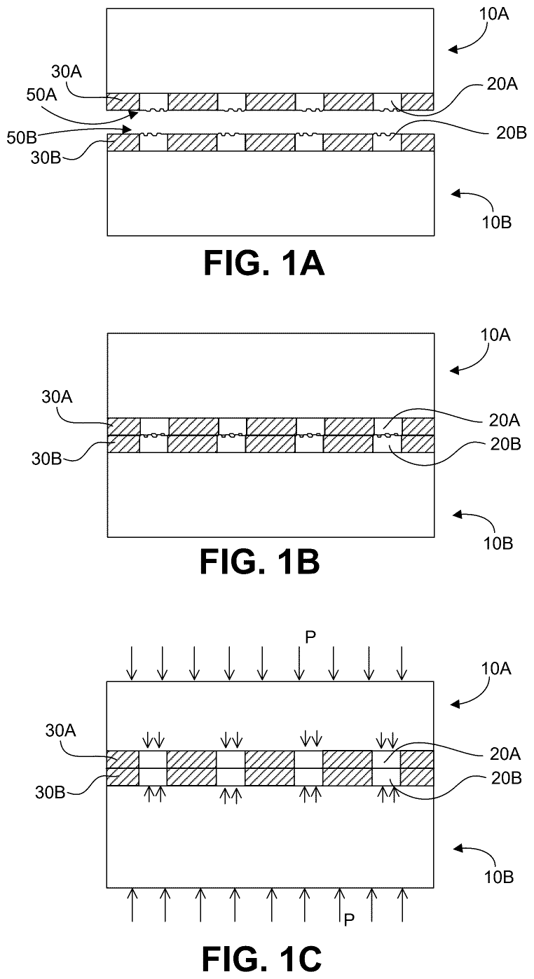

FIGS. 1A-1C provide schematic illustrations of a typical hybrid bonding process involving two devices, 10A and 10B. Each device may include interconnects or bumps, 20A and 20B, surrounded by a layer of a dielectric material, 30A and 30B. As depicted in FIG. 1C, following the hybrid bonding process, the exposed surfaces of the bumps and dielectric layers on the two devices, 10A and 10B, are joined together. For simplicity, and except when specifying individual features, in this disclosure, common elements of two bonded devices will be referred to collectively and individually using the same reference numbers. For instance, devices 10A and 10B will be referred to as device(s) 10, dielectric material 30A and 30B as dielectric material(s) 30, and so forth. Furthermore, for brevity, dielectric material 30 may be simply referred as dielectric 30.

Bumps 20 serve as conductive interconnect structures that establish electrical connections between a die (integrated circuit) and a substrate. Typically, cylindrical and often made from metals like copper, these bumps are significantly smaller than traditional interconnects, such as flip-chip solder bumps or wire bonds. Their compact size makes them particularly suited for high-density applications, including 2.5D and 3D packaging technologies, where close spacing is required for stacked or tightly arranged components. In the embodiments presented, bumps 20 have a diameter of ≤20 microns and a pitch of ≤30 microns. In other embodiments, the bump size may be reduced to ≤10 microns with a pitch of ≤20 microns. For even smaller designs, the bump size may be ≤5 microns, with a pitch of ≤10 microns.

In the devices described here, bumps 20 may be formed from any electrically conductive material suitable for IC fabrication, providing adequate conductivity, mechanical strength, and reliability. They can vary in shape (e.g., cylindrical). Examples include metals like copper or gold, or high-temperature solder alloys, such as those based on gold or silver, in specific embodiments. For the dielectric 30, a variety of materials may be used, including silicon dioxide (SiO₂), silicon oxide (SiOx), silicon nitride (Si₃N₄), aluminum oxide (Al₂O₃), polyimides like Kapton, low-k dielectrics such as fluorinated silicon oxide and porous organosilicates, or high-k dielectrics such as hafnium oxide (HfO₂) and zirconium oxide (ZrO₂).

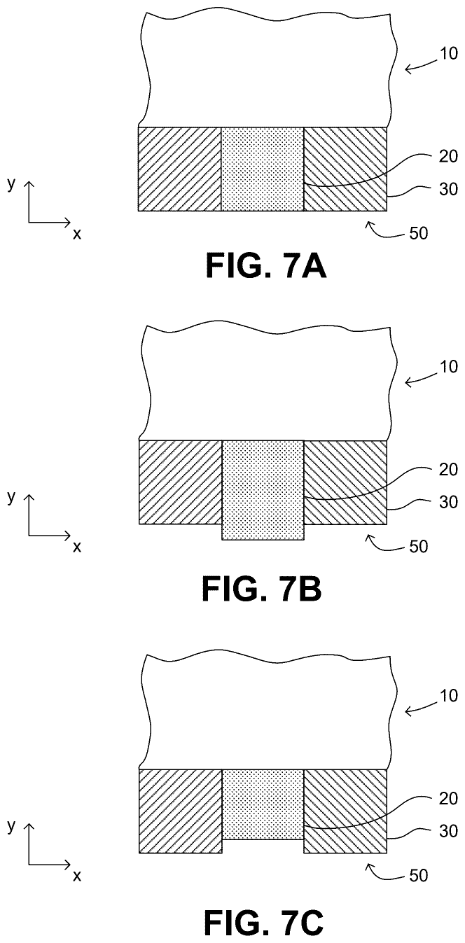

It is worth mentioning that although the far ends of the bumps 20 and dielectrics 30 (i.e., the ends situated away from the corresponding device 10) are shown to lie in the same plane in FIG. 1A, this depiction is merely illustrative. In practice, the far ends of the dielectric 30 and bump 20 may either align on a single plane (i.e., ΔY=0), as demonstrated in FIG. 7A, or may be vertically offset (i.e., ΔY≠0), as illustrated in FIGS. 7B and 7C. For instance, in certain embodiments depicted in FIG. 7B, the bump 20 may extend through the dielectric 30 and protrude beyond its far end. Alternatively, in some embodiments shown in FIG. 7C, the bump 20 may not fully extend through the dielectric 30, resulting in a recessed structure at the far ends of the bump 20 and dielectric 30. It should be noted that the protrusion illustrated in FIG. 7B and the recess depicted in FIG. 7C are exaggerated for clarity; in reality, their dimensions may be on the scale of microns.

In some embodiments, the bonding surfaces 50 (e.g., the surfaces that will be bonded together) of one or both of the devices 10 may be polished (e.g., by Chemical Mechanical Polishing (CMP)) and cleaned to prepare them for hybrid bonding prior to the bonding. The bonding surfaces 50 of one or both the devices 10 may also be “activated” to promote bonding. Activation refers to the process of preparing the bonding surfaces 50 to achieve optimal adhesion and electrical connectivity. This may involve modifying the surfaces of dielectric 30 and/or bumps 20 to enhance their chemical and physical properties. Activation may include steps such as cleaning to remove contaminants, surface treatment to improve wettability, and plasma or chemical activation to create reactive sites. These processes ensure that the surfaces are primed for direct bonding at the atomic scale, enabling reliable and low-resistance connections between the two devices 10.

Activation may involve treating the surfaces with plasma or other techniques to create reactive sites or chemical groups that facilitate bonding. For example, in some embodiments, the surfaces may be activated to make the organic surfaces (e.g., dielectric) of the wafers hydrophilic. A hydrophilic surface refers to a surface that has a strong affinity for water, meaning it attracts and readily interacts with water molecules. It some embodiments, the surfaces of the wafers may be treated with compounds such as, for example, DI water, NaOH, etc., to make the surfaces hydrophilic.

Plasma activation is an exemplary activation technique that may be used to prepare semiconductor devices for bonding. Before plasma activation, the bonding surfaces 50 of both devices 10 may be cleaned to remove any contaminants, particles, or organic residues to ensure that these surfaces are clean and free of impurities. The cleaned devices 10 are then subjected to a plasma treatment, e.g., in a vacuum chamber or a controlled atmosphere. Plasma is a partially ionized gas consisting of charged particles (ions and electrons) and reactive species (such as radicals and excited atoms or molecules). During plasma treatment, the energetic species in the plasma interact with the bonding surfaces 50 causing physical and chemical changes to the surface properties. These changes may include the removal of surface contaminants, the creation of reactive functional groups (such as hydroxyl groups or dangling bonds), and the generation of micro-scale roughness or texture on the surface. The modified surface created by plasma activation may enhance the adhesion between the bonding surfaces 50 of devices 10. The reactive functional groups and increased surface energy may facilitate stronger molecular interactions and bonds at the bonding interface.

An example of a plasma activation process for hybrid bonding two semiconductor devices 10 featuring copper bumps 20 surrounded by SiO₂ dielectric 30 involves exposing the devices 10 to a plasma environment. This process typically utilizes gases such as oxygen, nitrogen, or a combination of both. The plasma, generated within a low-pressure chamber using radio-frequency power, produces reactive ions and radicals that interact with the bonding surfaces 50. This interaction modifies the SiO₂ dielectric by introducing reactive functional groups, such as hydroxyl groups, which enhance surface energy and wettability. Additionally, the plasma removes oxidation layers from the copper bumps 20 ensuring a clean, reactive surface for strong electrical connections during hybrid bonding. The activation process described above is merely exemplary. In general, any suitable activation process may be used. In some embodiments, the activation process of the devices may be carried out in a modular apparatus.

After activation, the bonding surfaces 50 of the two devices 10 may be aligned and placed one on top of the other, as illustrated in FIG. 1B. The process of aligning the devices involves precisely positioning and orienting their bonding surfaces 50 relative to each other prior to joining them. Proper alignment ensures that the features, patterns, or structures on the two bonding surfaces 50 are accurately matched and positioned as intended. For example, the devices 10A and 10B may be aligned such that bumps 20A are positioned on (or above) the corresponding bump 20B of device 10B. In some embodiments, one or both devices 10 may include alignment marks or fiducials, which are predefined patterns or features serving as reference points for alignment. These fiducials enable precise positioning, reducing the risk of misalignment after bonding.

In some embodiments, an alignment system or tool may be utilized to detect and align these alignment marks or other relevant features. Tools such as optical microscopes, infrared alignment systems, or advanced imaging systems can visually and/or electronically detect alignment marks and guide the positioning process. In some embodiments, the alignment system may incorporate feedback mechanisms that provide real-time data and control. Such systems allow for continuous monitoring and precise adjustments of the relative positions and orientations of the devices during the alignment process. This level of precision is especially important for hybrid bonding, where atomic-scale accuracy is necessary to achieve robust electrical and mechanical connections between the devices.

After alignment, as shown in FIG. 1C, the two precisely aligned devices 10 are pressed together using controlled pressure to ensure intimate contact between their bonding surfaces 50. This pressure helps eliminate any gaps or air pockets, allowing the surfaces to interact at the atomic level. The process may be accompanied by heating, which activates the bonding mechanism, such as diffusion or chemical reactions, to create strong and reliable connections. The applied temperature and pressure may depend on the application (e.g., size of device, number of bumps, material of bumps, etc.). In embodiments of devices with copper bumps, the applied temperature may be between about 200-250° C. and the applied pressure may be between about 10-100 MPa. The combination of precise alignment, controlled pressure, and thermal activation may achieve successful hybrid bonding of the semiconductor devices 10.

Precisely aligning two devices for hybrid bonding poses significant challenges, particularly in achieving precise alignment and maintaining alignment accuracy throughout the bonding process. As semiconductor devices continue to shrink in size and become increasingly densely packed, the task of aligning their bonding surfaces grows more complex. If used, alignment marks or fiducials may be extremely small and closely spaced, making them difficult to detect and position accurately. In many hybrid bonding applications, sub-micron or nanometer-level alignment accuracy may be needed essential to ensure the proper alignment of critical features and structures in the bonded devices, which adds to the technical complexity. Achieving and maintaining such high accuracy requires sophisticated alignment systems equipped with advanced imaging technology, real-time feedback mechanisms, and precision control tools.

Furthermore, semiconductor devices often exhibit non-uniformities and warpage caused by factors such as thermal stress, variations in material properties, and differences in processing conditions. For example, coefficient of expansion mismatch between the materials used in the fabrication of the devices can cause these devices to warp during heating and cooling. These non-uniformities can impact the flatness and consistency of the bonding surfaces, making it difficult to achieve uniform alignment across the entire bonding area. Such irregularities may necessitate additional measures or compensatory techniques to ensure reliable bonding.

In high-volume manufacturing environments, the challenge becomes even more pronounced, as alignment accuracy must be balanced with process efficiency to maintain reasonable throughput and optimize productivity. This may require innovative approaches and systems that not only address alignment challenges but also streamline the process to enhance overall manufacturing yield. Embodiments of the current disclosure address these alignment challenges and provide solutions that simplify and improve the alignment of two devices for hybrid bonding.

Unless stated otherwise, all descriptions provided in relation to one embodiment are equally applicable to other embodiments. For instance, the description of the structure of devices 10, bumps 20, dielectrics 30, and the hybrid bonding process as discussed with reference to FIGS. 1A-1C is also applicable to devices 100, bumps 120, dielectrics 130, and processes 300, 500 described in the embodiments described below.

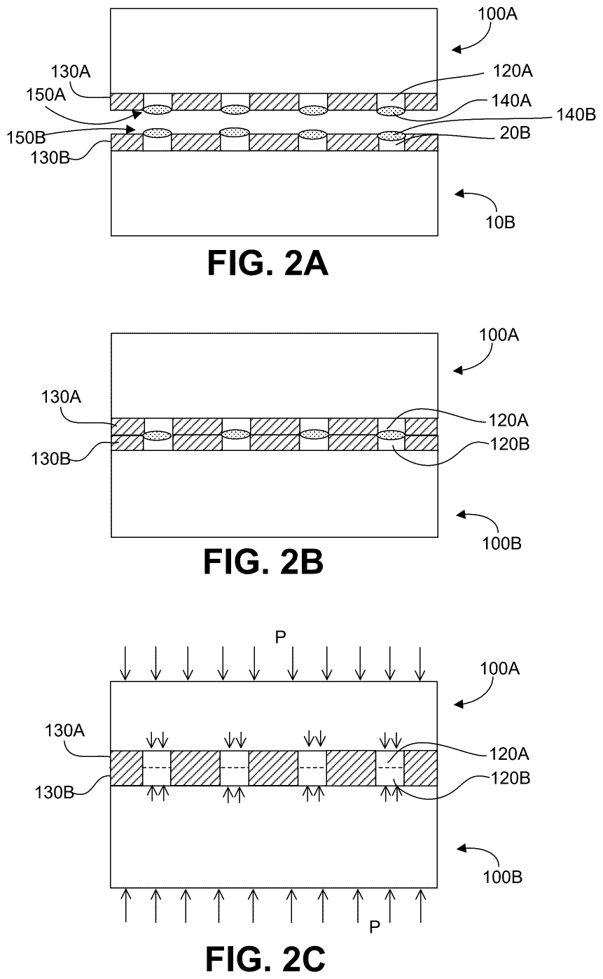

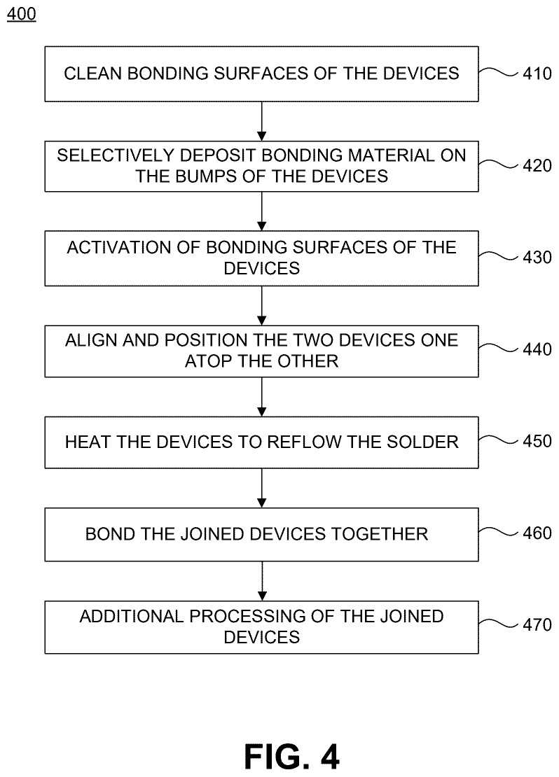

FIGS. 2A-2C schematically illustrate one embodiment of the disclosed process for bonding two devices 100A, 100B using hybrid bonding. As explained with reference to FIG. 1A-1C, both devices, 100A and 100B, have bonding surfaces, 150A and 150B, which include interconnects or bumps, 120A and 120B, surrounded by dielectric layers, 130A and 130B. As described in reference to FIGS. 1A-1C, bumps 120 and dielectric 130 can be made from any appropriate material and can have size, shape, and configuration. For example, bumps 120 have a diameter of ≤20 microns and a pitch of ≤30 microns. In some embodiments, the bump size may be reduced to ≤10 microns with a pitch of ≤20 microns, while in some embodiments, the bump size may be ≤5 microns, with a pitch of ≤10 microns. In the discussion below, only the differences between the process of FIGS. 1A-1C and the process of FIGS. 2A-2C will be described. FIG. 4 is a flow chart of an exemplary process for bonding two devices 100 using hybrid bonding. In the discussion that follows, reference will be made to FIGS. 2A-2C and FIG. 4.

The bonding surfaces 150 of the two devices 100 are first cleaned (step 410). This process involves removing contaminants, particles, and organic residues through methods such as, for example, plasma cleaning, chemical treatments, or ultrasonic cleaning. Plasma cleaning uses ionized gas to strip away impurities at a microscopic level, while chemical treatments dissolve surface residues. In some cases, a mechanical polishing step (e.g., CMP) may also be applied to achieve smoother and more uniform surfaces. Cleaning the bonding surfaces 150 assists in achieving a defect-free bond and reliable performance of the bonded devices 100.

A desired bonding material 140A, 140B is then selectively disposed on the bumps 120A, 120B of the two devices (Step 420). FIG. 2A illustrates the two devices 100 with the bonding material 140 selectively deposited on their bumps 120. In this context, selectively disposed (deposited, applied, etc.) refers to the application of the bonding material 140 exclusively (or primarily) onto the surface of the bumps 120 while avoiding (or minimizing) deposition on the surrounding dielectric 130. This selective process ensures that the bonding material 140 adheres only on (or mainly on) the conductive bumps 120 and not on the dielectric 130.

Any known process may be used to selectively deposit the bonding material 140 on the bumps 120. In some embodiments, a process that only deposits the bonding material on the material of the bumps 120 (e.g., electroless deposition) may be used to selectively deposit bonding material 140 on bumps 120. In some embodiments, a mask may be used to selectively deposit the bonding material on bumps 120. For example, the surface of the dielectric 130 on the bonding surface 150 may be covered using a mask and bonding material 140 may be selectively deposited on the bumps 120 through openings on the mask. In some embodiments, bonding material 140 may be deposited over the entire bonding surface 150 and then selectively removed from atop the dielectric 130 to retain bonding material 140 on bumps 120.

Bonding material 140 can be selected based on specific application requirements and is typically a low melting temperature material, such as low melting temperature solder. Any electrically conductive material with a melting temperature below approximately 200° C. (or below about 190° C., or below about 160° C., etc.) may be used. For example, materials like indium (melting temperature 156.6° C.) or eutectic lead-tin solder (63% tin and 37% lead, melting temperature around 183° C.) may be chosen as bonding material 140. Other options include bismuth-based alloys, such as eutectic bismuth-tin (58% Bi, 42% Sn) with a melting temperature of about 130° C., indium-tin (In—Sn) with a melting range of 118-125° C. depending on composition, bismuth-tin-silver with a melting temperature around 140° C., and bismuth-indium (Bi—In) with a melting temperature near 150° C. depending on composition. Additionally, commercially available low melting temperature alloys, such as Indium Corporation's Durafuse® LT, which reflows below 200° C., may be utilized in certain embodiments.

Bonding materials 140 used for the bumps 120 on the two devices 110 may either be the same or different. For example, in some embodiments, a first bonding material 140A may be applied to the bumps 120A of device 100A, while a second, different bonding material 140B may be applied to the bumps 120B of device 100B. Alternatively, the same bonding material may be used for the bumps 120 of both devices 100 in certain embodiments. To simplify the following discussion, it is assumed that the same bonding material 140 is applied to the bumps 120 of both devices, and this bonding material 140 will hereafter be referred to as solder 140.

In some embodiments, the bonding surfaces 150 of the two devices 100 may undergo an activation process, as outlined with reference to FIGS. 1A-1C (step 430). As will be discussed later, this activation step may be omitted or adjusted in some cases. Thereafter, the devices are aligned and positioned atop one another, as previously described (step 440). During this step, the devices 100 are arranged so that their bonding surfaces 150 and bumps 120 are roughly aligned. For example, the alignment may entail positioning the two devices, 100A and 100B, such that at least a portion of the solder 140A on bumps 120A (of device 100A) is situated on or above the solder 140B on bumps 120B (of device 100B), thereby ensuring either proximity or direct contact. FIG. 2B illustrates the two devices 100 positioned one above the other.

Once the devices are roughly aligned, they can be heated (step 450) to cause the solder 140 to melt (or change from solid-like phase to liquid-like phase) and facilitate precise self-alignment of the two devices 100 through surface tension. Typically, the devices may be heated to a temperature equal to, or slightly above, the phase transition temperature of solder 140 in this step. As used herein, the term “phase transition temperature” broadly refers to a temperature in the temperature range at which solder 140 undergoes a phase change. This includes the melting temperature (solid to liquid) for pure elements, the eutectic temperature for eutectic solder alloys, or a temperature within the solidus-liquidus range for non-eutectic solder alloys. For instance, if solder 140 is pure indium, its phase transition temperature corresponds to its melting point of 157° C. If it is eutectic indium-tin solder, the phase transition temperature is its eutectic temperature of approximately 118° C. In the case of a non-eutectic solder like 58% tin and 42% bismuth (58Sn-42Bi), the phase transition temperature may be any value between the solidus temperature of about 139° C. and the liquidus temperature of about 170° C. (including the two end points).

In some embodiments, the devices may be heated (in step 450) in a reducing environment. Heating the devices in a reducing environment refers to the process of exposing the devices to solder melting (or reflow) temperatures within an atmosphere that contains reducing agents, such as hydrogen gas or forming gas (a mixture of nitrogen and hydrogen). The purpose of this environment is to remove surface oxides and contaminants from the solder and the device's bonding surfaces (e.g., bumps 120). The heating profile may be carefully managed to raise the temperature above the melting point of the solder 140, allowing it to liquefy and flow.

Surface tension-driven self-alignment is a phenomenon where the two devices automatically align themselves in a specific orientation due to the forces exerted by the surface tension of the molten droplets (e.g., liquid) of solder 140 between them. In this case, upon melting, the liquid solder 140 creates surface tension forces that automatically adjust (e.g., horizontally move the devices relative to one another) the two devices 100 and align the two bonding surfaces 150. This process ensures the required precise positioning for hybrid bonding by leveraging the natural tendency of the liquid to minimize its surface energy, effectively pulling the surfaces into optimal alignment. By leveraging the forces of surface tension, this self-alignment technique can achieve high levels of alignment accuracy and repeatability without the need for complex external alignment systems or mechanisms.

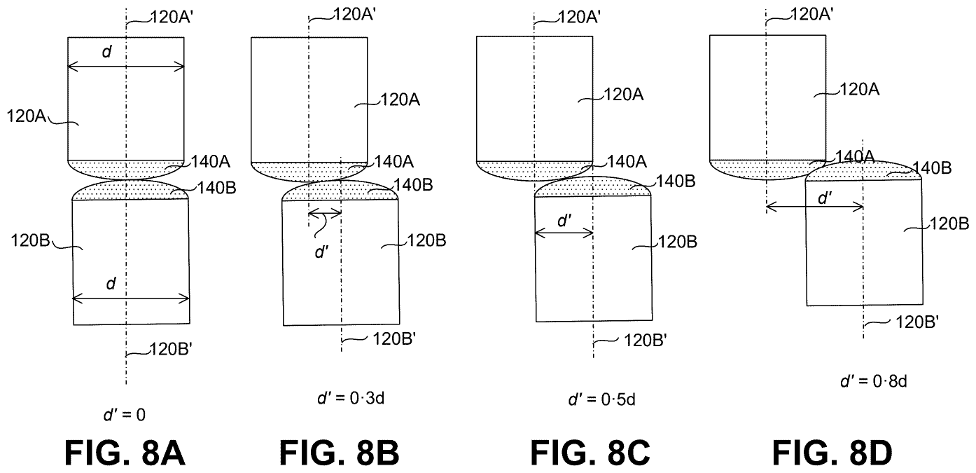

With reference to FIGS. 8A-8D, “roughly aligned” refers to the placement of the two devices 100 such that the bump centers 120A′, 120B′ of a corresponding pair of bumps 120 are within a certain offset range. This alignment ensures that, during the subsequent reflow process of solder 140, the molten solder can self-align the devices due to surface tension forces and achieve proper electrical and mechanical connections. In embodiments of the current disclosure, the maximum permissible offset “d” between the bump centers (d′=ΔX_{120A′-120B′}) varies based on factors such as bump size, pitch, and solder properties. In some embodiments, the offset d′ should not exceed about 30% of the bump diameter “d” (i.e., d′≤0.3 d) to ensure successful bonding. In some embodiments of the current disclosure, the two devices 100 may be roughly aligned such that the bump offset d does not exceed about half the bump diameter d (i.e., d′≤0.5 d). While in some embodiments, the bump offset d′ should not exceed about 80% of the bump diameter d (i.e., d′≤0.8 d). Beyond this range (|d′|≤0.8 d) the solder 140 may fail to self-align the devices 100 due to surface tension forces. Importantly, the alignment precision required in this embodiment is less stringent than that discussed in relation to FIGS. 1A-1C, due to the self-aligning mechanism of solder 140.

In some embodiments, vibration energy may be directed at the interface (bonding surfaces 150) to promote self-alignment. For example, one or more ultrasonic transducers (or megasonic transducers) may direct vibration energy to the bonding surfaces 150 when the two devices 100 are heated. Vibration assists surface tension-driven self-alignment by introducing controlled mechanical oscillations that help overcome minor misalignments (e.g., between bumps 120 or other mating features of the two devices 100) and reduce friction between the bonding surfaces 150. These vibrations allow the liquid solder 140 to flow more freely, enhancing the surface tension forces that drive the alignment. Additionally, vibration can help eliminate trapped air bubbles in the liquid solder 140 and ensure uniform contact between the bonding surfaces 150, further improving the precision and reliability of the self-alignment process. In some embodiments, pressure may be applied during the heating process to press the two devices 100 together, causing the liquefied solder 140 to flow out from between the bumps 120, allowing the bumps 120 of both devices 100 to come into direct contact

Once the solder 140 has reflowed, the devices 100 are gradually cooled to solidify the solder and join the two devices 100 together. After reflow, the joined devices may be subject to a bonding process to firmly join the device 100 together (Step 460). In some embodiments, the applied bonding process (step 460) may include an annealing process to join or fuse together the mutually facing surfaces of the dielectrics 130 of the two devices 100 together. As will be described subsequently, in some embodiments, the applied bonding process (step 460) may include filling a gap between the mutually facing surfaces of the dielectrics 130 with an underfill material to join the dielectrics 130 together using the underfill. In some exemplary embodiments, the applied annealing process may be a two-step annealing process comprising, for example, a low-temperature anneal, and a high-temperature anneal. The low-temperature anneal may be a low temperature annealing process (e.g., from room temperature to a first temperature) to join the surfaces of the dielectrics 130 of the two devices 100 together. In some embodiments, the two devices may be held at this first temperature for an extended time period (e.g., a first time period). During low-temperature anneal, the surfaces of the dielectric 130 may be joined together by covalent bonding. In some embodiments, as illustrated in FIG. 2C, the two devices 100 may be pressed together during the annealing process. In some embodiments, the applied pressure on the devices may be between about 10-100 MPa.

The joined devices 100 after low-temperature anneal may be subject to high-temperature anneal. High-temperature anneal may be a high temperature annealing process where annealing of the joined devices 100 is performed at a second temperature higher than the first temperature. During high-temperature anneal, the material of the contacting bumps 120 of the two devices 100 join together by intermixing (or alloying). In an exemplary device using copper bumps 120, copper atoms from the bumps of one device (e.g., bumps 120A) intermix or alloy with the bumps of the other device (e.g., bumps 120B) to firmly bond the two devices 100 together. This bonding process occurs at the atomic scale and results in a strong, low-resistance electrical connection between the devices 100.

The first and second temperatures can vary based on the application, including the materials used for dielectric 130, bumps 120, and solder 140. Typically, the first temperature ranges from room temperature to the second temperature. In some cases, the first temperature may be up to approximately 100° C. (e.g., 50° C., 70° C., 80° C., 90° C., etc.), while in other instances, it may fall between 100° C. and 200° C. (e.g., 120° C., 140° C., 160° C., 180° C., etc.). Additionally, in certain embodiments, the first temperature may exceed 200° C. (e.g., 220° C., 240° C., 260° C., 280° C., 300° C., etc.). Regardless of their values, the second temperature is generally higher than the first. The first and second time periods also depend on the application and can range from 5 minutes to 1 hour (e.g., 5 minutes, 10 minutes, 20 minutes, 30 minutes, 40 minutes, 50 minutes, 60 minutes, etc.), with the durations being equal or different.

After bonding, in some embodiments, the bonded devices 100 may undergo additional processing steps such as annealing or curing to strengthen the bonds and improve the overall reliability of the interconnects (step 470). In some embodiments, the joined devices may be subject to cleaning to remove any flux residues or contaminants, and inspection using techniques like X-ray imaging or optical microscopy to verify bond integrity and alignment. Additionally, the device may undergo annealing to enhance the mechanical and electrical properties of the joints, followed by electrical testing to ensure proper performance.

Notably, in some embodiments, activation may not be performed in step 430 prior to placing devices 100 one atop the other for bonding (step 430) to avoid the formation of an oxide (e.g., an oxide coating) on the bumps 120 during the bonding process. In some embodiments, other types of activation may be performed but plasma activation may not be performed. In some embodiments, plasma activation may be performed but it may be tailored to avoid formation of an oxide on the bumps 120.

Method or process 400 of FIG. 4 enables the connection of semiconductor devices through hybrid bonding. In some embodiments, it begins with preparing a first device that has a surface (e.g., bonding surface) featuring multiple metallic bumps extending outward through a dielectric layer, with their end surfaces exposed (see, e.g., FIGS. 7A-7C). The term “preparing” broadly refers to the act of making the device available or accessible, whether through fabrication, acquisition, facilitation, or other means of securing its presence or availability for use in the process. Similarly, a second device is prepared with a surface containing metallic bumps that protrude through its dielectric layer, exposing their end surfaces. Solder material is applied to the exposed end surfaces of the metallic bumps on both devices. The devices are then aligned such that at least a portion of the solder material on the metallic bumps of the first device makes contact with the solder material on the metallic bumps of the second device. As explained with reference to FIGS. 8A-8D, in some embodiments, the two devices may be roughly aligned such that the magnitude of the bump offset is less than or equal to about 80% of the diameter of one of the bumps (i.e., |d′|≤0.8 d).

Once aligned, the devices are heated to reflow the solder material, resulting in the joining of the metallic bumps between the two devices. During the reflow, surface tension forces in the molten solder may properly align the roughly aligned devices by surface tension. Following solder reflow to join the end surfaces of the first copper bumps to the end surfaces of the second copper bumps, the bonding surface of the first dielectric layer is bonded to the bonding surface of the second dielectric layer. In the present disclosure, the term “bonding” is intended to encompass multiple scenarios of connecting two surfaces. It includes direct bonding, where the bonding surfaces, such as the facing surfaces of the dielectrics 130 of the two devices 100, are joined or fused together without any intermediary material. The term “bonding” also encompasses bonding through the use of an interfacial material, such as an underfill material, which fills the gap between the bonding surfaces and connect the dielectrics 130 together through the underfill material. Thus, in this disclosure, the term “bonding” serves as a broad term that captures both direct physical attachment and attachment mediated by an underfill layer.

In some embodiments, bonding of the bonding surface of the first dielectric layer to the bonding surface of the second dielectric layer may be achieved via an underfill that fills the gap between the two bonding surfaces. While in some embodiments, this bonding may be achieved via an annealing process, which bonds the dielectric layers together and securely joins each metallic bump on the first device to its corresponding metallic bump on the second device. In some embodiments, the annealing process involves first performing low-temperature annealing to bond the first dielectric layer to the second dielectric layer. This low-temperature annealing is achieved by maintaining the first and second devices at a temperature between approximately 100-200° C. for a duration greater than zero. Following the low-temperature annealing, the process proceeds to high-temperature annealing to bond each bump of the first set of copper bumps to a corresponding bump of the second set of copper bumps. The high-temperature annealing is carried out by maintaining the devices at a temperature higher than the low-temperature annealing temperature for a duration that may be equal to or different from the duration of the low-temperature annealing.

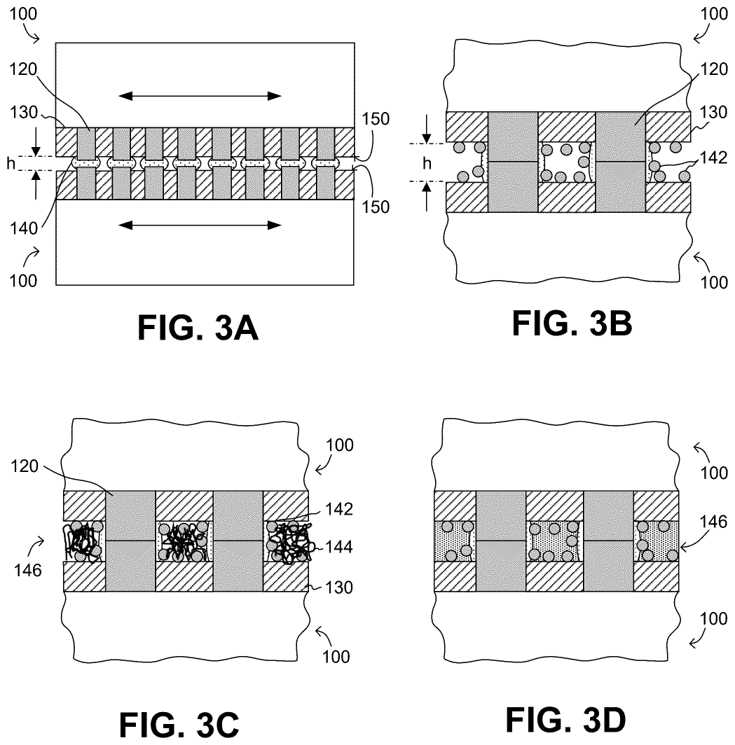

In the embodiment described with reference to FIGS. 2A-2C, a low melting temperature material (e.g., solder 140) is selectively deposited on the metal bumps 120, and the surface tension forces that results when this material melts is used to automatically self-align the two devices 100 together. In some embodiments, the devices 100 are designed to float freely on the molten solder, enabling the surface tension of the solder 140 to naturally align the devices. To facilitate this, the bumps 120 are configured to extend through the dielectric 130 and protrude beyond its far edge. Specifically, at the bonding surface 150 of the devices 100, the bumps 120 project outward from the far end of the dielectric, as depicted in FIG. 7B. For example, as illustrated in FIG. 3A, during step 450 of process 400 (FIG. 4), the standoff “h” between the two dielectric surfaces 130 may allow the devices 100 to adjust their horizontal position relative to one another and promote precise self-alignment. In such embodiments, after reflow of solder 140, the opposing surfaces of the two dielectrics 130 may not contact each other. Instead, these dielectric surfaces may remain separated by vertical standoff “h”. For clarity, FIG. 3A exaggerates this standoff. The standoff may depend on the specific application and is not a requirement. It some embodiments, it may be less than about 5 microns (0<h>5 microns), while in some embodiments, it may vary between about 0.5-2 microns.

In some embodiments, rather than annealing the two joined devices 100 after reflow (in step 460 of process 400), an underfill process may instead be employed to fill the gap or standoff “h” between the dielectric surfaces and thereby bond the dielectric surfaces together via the underfill. The choice of underfill process depends, among other things, on the standoff “h” and the pitch of the bumps 120. In typical semiconductor packages, such as flip chip bonded packages, the standoff generally ranges from tens to hundreds of microns, often exceeding 20 microns. This gap must be completely filled by the underfill material to ensure both mechanical stability and thermal management. For standoffs greater than approximately 20 microns, underfill materials are specially formulated to flow into the gap via capillary action, effectively filling the space without leaving voids and establishing a strong bond between the devices. However, as the standoff “h” and the pitch of the bumps 120 decrease, conventional epoxy underfills may not be suitable for efficiently and effectively filling the gap between the two devices 100.

In some embodiments disclosed herein, the standoff “h” between the two devices 100 (illustrated in FIG. 3A) can be underfilled using a polymer brush technique. As shown schematically in FIG. 3B, following solder reflow, an initiator 142 is applied to the bonding surfaces 150 of the two devices 100, as well as to any exposed areas of the bumps 120 and solidified solder 140. This initiator 142 is introduced by exposing the surfaces to a vapor of organic halide molecules. These halide molecules chemically adhere to the surfaces (a process known as initiator grafting), forming covalent bonds and creating a reactive layer. Polymerization is then triggered by subjecting the initiator-coated surfaces to an appropriate catalytic system or initiator, delivered in either liquid or vapor form. As illustrated in FIG. 3C, this process results in the growth of polymer chains 144 from the attached halide groups, producing a dense layer of polymer brushes around the bonded interconnect structures, which functions as the underfill 146. In some embodiments, the bonded device surfaces are selectively treated with the organic halide vapor by sealing or masking areas not intended for exposure.

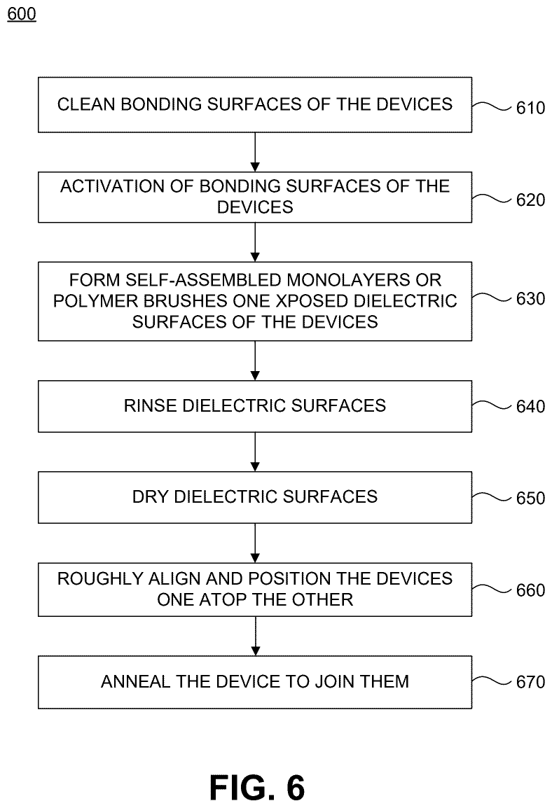

Exemplary methods for forming a polymer brush will be described in later sections (e.g., e.g., polymer brush 160 formed using process 600 of FIG. 6). Several established techniques for creating polymer brushes on surfaces are known, as outlined in U.S. Patent Application Publication Nos. US 2023/0109614 A1, US 2022/0242988 A1, US 2019/0043754 A1, US 2016/0351449 A1, US 2014/0142249 A1, US 2012/0088192 A1, US 2017/0162380 A1, US 2016/0244581 A1, and US 2016/0186004 A1, all of which are incorporated herein by reference. These methods typically start with the formation of a polymerization initiator on the target surface. The surface is then exposed to a combination of suitable monomers and additives-such as catalysts, ligands, and solvents-that facilitate polymerization and enable the formation of the polymer brush. The selection of initiators and monomers is tailored to achieve specific properties in the polymer brushes, depending on their intended application, such as use as underfills. In some cases, multiple layers of polymer brushes can be generated by sequentially repeating the polymer brush formation process. Any of these established techniques can be adapted to create the polymer brush underfill 146 described in this disclosure.

A polymer brush underfill 146 can be structurally identified by its unique arrangement of polymer chains 144 that are densely tethered to a surface (e.g., surface of dielectric 130). These polymer chains 144 extend away from the surface in a brush-like configuration, creating a uniform and organized layer. This structure is distinct from other known epoxy or polymer underfills, which typically consist of bulk, crosslinked polymer networks that lack the ordered, surface-tethered arrangement found in polymer brushes.

Forming an underfill of a polymer brush 146 enables precise control over the brush characteristics, such as density and composition, enhancing the material's properties to be used as an underfill. In some embodiments, the catalyst and solvent mixture may contain thermally conductive nanoparticles to enhance thermal conductivity of the resulting polymer brush underfill 146. Suitable nanoparticles may include aluminum nitride, boron nitride, nano diamonds etc. In some embodiments, after forming the polymer brush underfill, the component may then be annealed to densify the polymer brush underfill 146 as illustrated in FIG. 3D. Annealing the polymer brush underfill 146 involves heating the component to a specific temperature for a designated duration. This process allows the polymer chains in the polymer brush to rearrange, relax, and reach a thermodynamically stable state. The temperature is typically set below the polymer's glass transition temperature to avoid melting while promoting chain mobility. Annealing can enhance the uniformity, density, and mechanical properties of the polymer brush, making it more effective as an underfill.

In some embodiments, as described with reference to FIG. 7C, the bumps 120 may extend through the dielectric 130, forming a recess at the far end of each bump on the bonding surface 150. In these cases, the standoff created between the dielectric surfaces by the solder 140 deposited on the bumps during step 420 of process 400 allows the devices 100 to move relative to one another and self-align during the solder reflow process. The quantity of solder 140 deposited can be calibrated so that upon solidification, the solder completely fills the recess, enabling the dielectrics 130 of the devices to come into contact. Subsequently, during the annealing step (step 460), these dielectrics 130 may be joined together. In some embodiments, although not depicted in the figures, features, such as cavities, may be incorporated into the dielectric surfaces. These cavities, located near the bumps 120, may be designed to capture and hold the molten solder 140 from the bumps 120 during the reflow process. By accommodating the flow of molten solder, these solder-retention cavities allow the corresponding bumps 120 and dielectrics 130 of the two devices 100 to make direct contact and form a strong bond. This configuration aids in achieving precise alignment and stable bonding of the devices during assembly.

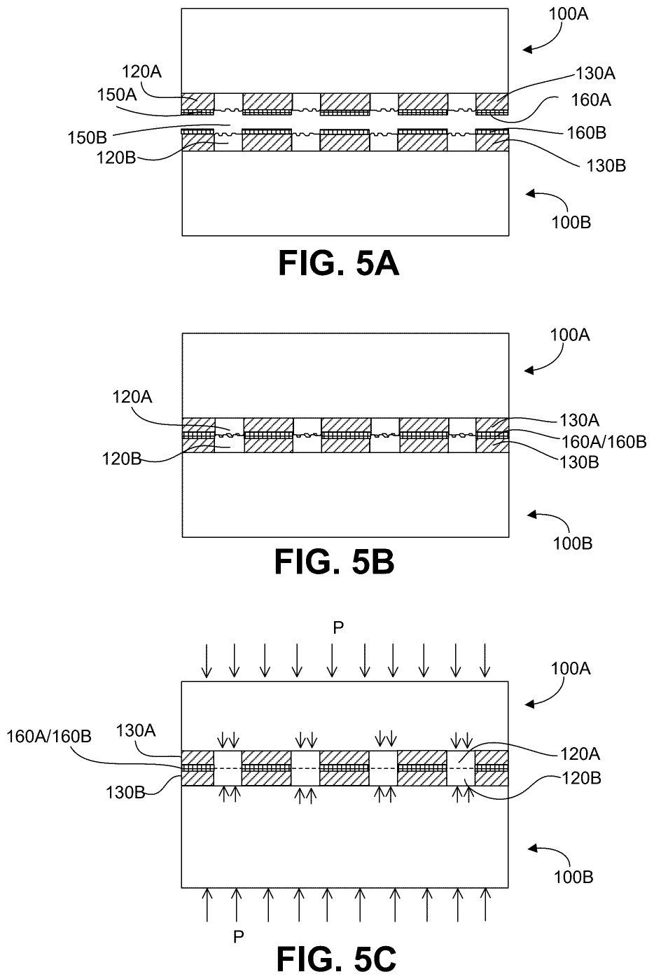

In the above described embodiments, the bump 120 is used for self-aligning the devices. Other methods may be employed to promote self-alignment. For example, in some embodiments, the mating surfaces of the dielectric 130 may be used to promote self-alignment of the two devices 100. FIGS. 5A-5C illustrate another exemplary embodiment of the current disclosure where the dielectric 130 on the bonding surfaces 150 are used for self-alignment. FIG. 6 is a flow chart of an exemplary method of using the dielectric surfaces to promote self-alignment. In the discussion below, only the differences between the process of FIGS. 5A-5C and the previously described processes will be described.

The bonding surfaces 150 of the devices 100 may be cleaned to prepare the devices for bonding (step 610). In some embodiments, after cleaning, the surfaces may be activated (step 620). In some embodiments, the activation step may be eliminated or combined with other steps (e.g., the next step). Self-assembled monolayers or polymer brushes may be formed on the exposed dielectric surfaces (step 630). Self-assembled monolayers (SAMs) may be formed on the exposed surfaces of the dielectric materials by any known process. For example, such SAMs may be formed by chemisorption, which involves the spontaneous adsorption of molecules onto the dielectric surface followed by the formation of a monolayer. Chemisorption is a process where molecules spontaneously adhere to a surface, such as a dielectric, through the formation of strong chemical bonds. This adsorption occurs at an atomic or molecular level and results in the creation of a monolayer—a single, uniform layer of molecules bonded to the surface. Unlike physisorption, which involves weak van der Waals forces, chemisorption involves specific chemical interactions that make it irreversible in most cases.

Different types of dielectrics 130 may have specific chemisorption properties based on their material characteristics and intended applications. For instance, in the case of silicon dioxide (SiO₂), chemisorption may enable molecules like organosilanes to adhere to the surface, forming a silane monolayer. For silicon nitride (Si₃N₄), the process may involve reactive gases such as ammonia (NH₃) to create nitride layers or functionalize the surface for subsequent chemical bonding. Low-k dielectrics may undergo chemisorption through surface treatments with precursors like organosilanes or plasma-based processes. For high-k dielectrics, such as hafnium oxide (HfO₂) or aluminum oxide (Al₂O₃), the process may involve hafnium or aluminum organometallic precursors during atomic layer deposition (ALD) to achieve a uniform monolayer. And in the case of polyimide dielectrics, chemisorption may entail surface functionalization.

In one exemplary embodiment, after completing the cleaning process in step 610 (e.g., to eliminate contaminants such as organic residues, native oxide layers, or particulate matter), the exposed surfaces of the dielectrics 130 may undergo an activation step (step 620). This activation can be achieved through techniques such as plasma treatment or chemical modification, which serve to introduce reactive functional groups or anchor sites to the surfaces, facilitating the subsequent attachment of self-assembled monolayers (SAM). Once cleaned and activated, the surfaces of dielectrics 130 are then exposed to a solution containing SAM molecules (step 630). This exposure can be carried out by methods such as pouring the solution onto the surfaces, immersing the surfaces in the solution, or other appropriate application techniques. SAM molecules typically consist of amphiphilic structures, having a hydrophobic tail and a hydrophilic head group. Upon exposure, these molecules adsorb onto the dielectric surfaces, either through chemical bonding or physisorption, a process driven by interactions such as hydrogen bonding, van der Waals forces, or electrostatic attraction.

In certain embodiments, polymer brushes may be formed on the dielectric surfaces in addition to SAM formation in step 630. As shown in FIG. 5A, polymer brushes 160A and 160B are generated on the exposed surfaces of the dielectrics 130A and 130B. This process begins with the attachment of initiator molecules to the cleaned and prepared surfaces. As described with reference to FIGS. 3A-3D, these initiators serve as anchor points for in-situ polymerization, allowing polymer chains to grow directly from the surface and form a functional polymer brush layer. Both SAM and polymer brush formations are utilized to modify the dielectric surface properties, such as enhancing adhesion or preparing the surface for subsequent processing steps.

A polymer brush is one or more densely packed layers of polymer chains tethered at one end to the surface of the dielectric 130. These polymer chains are attached via covalent bonds or other strong interactions, anchoring them securely to the surface. Due to the high density of the chains, steric repulsion causes them to extend outward from the surface, creating a brush-like structure. This structure typically consists of three key components: the anchor points where the chains are bonded to the surface, the extended polymer chains, and the uniform brush layer that resembles densely packed bristles. The thickness and density of the polymer brush depend on factors such as the length of the polymer chains and the attachment density.

During SAM formation, molecules self-assemble onto the dielectric surface to create a densely packed monolayer. This self-assembly is governed by the molecular structure of the SAM molecules and their interaction with the dielectric surface, resulting in a highly ordered arrangement. The hydrophobic tails of the molecules orient inward toward the dielectric 130, while the hydrophilic head groups face outward toward the solution. After the SAM layer is formed, the dielectric surfaces are typically rinsed with a solvent or solvent vapor to remove any unbound or loosely adhered SAM molecules and residual contaminants (step 640). This step helps improve the uniformity and purity of the SAM layer. Finally, the dielectric surfaces are dried, either under ambient conditions or with gentle heating, to eliminate solvent residues and stabilize the SAM layer (step 650).

It should be noted that the above-described process of forming a self-assembled monolayer (SAM) is only exemplary. Some other methods of forming suitable monolayers in embodiments of the current disclosure are described in the following prior art references—“Self-Assembled Monolayers of Thiolates on Metals as a Form of Nanotechnology,” by Ralph Nuzzo and George Schatz, published in 2001 in Chemical Reviews; “Self-assembled monolayers of alkyltrichlorosilanes: characterization and optimization,” by Daniel Primrose, et al., published in 1998 in Langmuir; “Preparation of self-assembled monolayers on silicon dioxide surfaces,” by A. Ulman, published in 1991 in Chemical Reviews; “Chemisorption of organosilanes on silicon dioxide,” by Henry W. Rohrs, published in 1998 in Thin Solid Films. PCT Publication WO2019196999A1 also describes methods of forming polymer brushes. Each of these references are incorporated by reference in their entirety herein.

Polymer brushes, regardless of their formation method, are composed of several monolayers and play a role in enabling self-alignment, thereby enhancing bonding uniformity. Once self-assembled monolayers or polymer brushes have formed on the exposed dielectric surfaces of the two devices 100, the devices are roughly aligned and stacked atop each other, as described in step 660 and earlier in step 440. During this process, the self-assembled monolayers or polymer brushes 160 on the dielectric surfaces of both devices come into contact, facilitating self-alignment of the bumps 120 on the two devices 100. The allowable offset values (d′) for the bump centers in this embodiment may correspond to those discussed with reference to FIGS. 2A-2C and 8A-8D.

FIG. 5B depicts the two devices 100 positioned one above the other. The two devices may then be subject to an annealing process to firmly join the devices 100 together (step 670). This annealing process may be the same as, or similar to, the annealing process of step 460 described previously. For example, the applied annealing process may be a two-step annealing process comprising a low-temperature anneal and a high-temperature anneal. During the low-temperature anneal, the polymer brushes on the surfaces of the dielectrics 130 may be joined together, and during the high-temperature anneal, the bumps 120 may fuse together. In some embodiments, as illustrated in FIG. 5C, as described with reference to the previously described embodiments, a pressure may be applied to press the two devices together during the annealing process. In some embodiments, as show in FIG. 5C, a thin layer of polymer brush 160 may be retained between the dielectric layers.

Importantly, similar to process 400 described in FIG. 4, process 600 of FIG. 6 requires significantly less precise alignment compared to the alignment process detailed in FIGS. 1A-1C. This reduction in alignment precision is due to the presence of self-assembled monolayers (SAM) or polymer brushes 160, which are formed on the mating surfaces of the dielectric materials of the two devices 100. These SAM layers or polymer brushes facilitate self-alignment, enabling the two devices 100 to adjust and align themselves more accurately upon contact. For example, when the polymer brushes 160 on the mating surfaces of the two devices 100 come into contact, they interact through intermolecular forces, such as van der Waals forces, electrostatic interactions, or hydrogen bonding. These forces cause the brushes to “recognize” and interact with each other, helping to guide the surfaces into alignment. For example, if the polymer brushes have complementary functional groups, such as a carboxyl group on one surface and an amine group on the other, they may form hydrogen bonds or ionic interactions, promoting precise alignment.

Polymer brushes 160 on the two dielectric surfaces may be designed to be chemically compatible with each other, such that upon contact the joined system has a tendency to minimize its free energy. This natural tendency leads the brushes to reorganize themselves and align the surfaces optimally. For instance, polymer brushes comprising polyethylene glycol (PEG) chains may align with each other due to their hydrophilic nature and flexibility, ensuring a tight and uniform interface. Regardless of the type of polymer brushes 160, the intermolecular forces or interactions provided by these surface treatments effectively guide the devices into proper alignment, reducing the need for external precision tools and simplifying the alignment process. This self-alignment capability not only streamlines the fabrication process but also enhances the overall reliability of the device assembly.

Thus, in embodiments of the current disclosure self-alignment assists in the precise alignment of the devices needed for hybrid bonding without the need of complex and time-consuming alignment systems and processes. The benefits and advantages of the disclosed processes are expected to become more evident as semiconductor devices gets further miniaturized.

In some embodiments, prior to or after bonding the two devices together, thinning of the devices (or the bonded devices) may be performed to reduce thickness and enable further integration or stacking of additional devices atop the bonded devices. Hybrid bonding may be used in conjunction with wafer thinning and stacking techniques. For example, multiple dies may be thinned to reduce thickness and then stacked together, and interconnected through hybrid bonding. This stacking approach enables the creation of 3D integrated circuits with enhanced performance and efficiency. The bonded structures may then be subjected to testing and characterization to assess the quality of the bonds, electrical properties of the interconnects, and overall functionality of the integrated devices. Following successful bonding and testing, the integrated devices may undergo further integration processes such as back-end-of-line (BEOL) processing, packaging, and assembly into final semiconductor products.

Like process 400, process 600 also involves connecting semiconductor devices using hybrid bonding. In some embodiments of process 600, a first device is prepared with a surface featuring multiple metallic (e.g., copper) bumps that extend outward through a dielectric layer applied to the surface, exposing their end surfaces. Similarly, a second device is prepared, also having a surface with metallic bumps that protrude through its dielectric layer to expose their end surfaces. To enhance bonding, one or more self-assembled monolayers or layers of polymer brushes are applied to the exposed surface of the first dielectric layer and the exposed surface of the second dielectric layer. Next, the first device is aligned (e.g., roughly aligned) with the second device, ensuring that the self-assembled monolayers or polymer brush layers on the first dielectric layer come into contact with those on the second dielectric layer and properly align the two devices. This alignment also positions at least a portion of the end surfaces of the metallic bumps on the first device to overlie or overlap with the end surfaces of the metallic bumps on the second device.

Finally, the devices undergo an annealing process to bond the first dielectric layer to the second dielectric layer and join each metallic bump on the first device to its corresponding metallic bump on the second device. The annealing process involves first performing low-temperature annealing to bond the first dielectric layer to the second dielectric layer. This low-temperature annealing is achieved by maintaining the first and second devices at a temperature between approximately 100° C. and 200° C. for a duration greater than zero. Following the low-temperature annealing, the process proceeds to high-temperature annealing to bond each bump of the first set of copper bumps to a corresponding bump of the second set of copper bumps. The high-temperature annealing is carried out by maintaining the devices at a temperature higher than the low-temperature annealing temperature for a duration that may be equal to or different from the duration of the low-temperature annealing.

As described in process 400 and process 600, the semiconductor devices may undergo activation prior to hybrid bonding. In some embodiments, the activation may be performed using a modular activation system. The modular system consists of multiple interconnected modules (900A-900F), each designed to perform specialized tasks in the activation process. The system may include a Front Opening Unified Pod (FOUP) (900A) for storing devices in a clean environment to prevent contamination and enabling automated handling. Cleaning modules (900B, 900C) may be employed to remove impurities, such as organic residues, native oxide layers, or particulate contaminants, using methods like wet cleaning or chemical treatments.

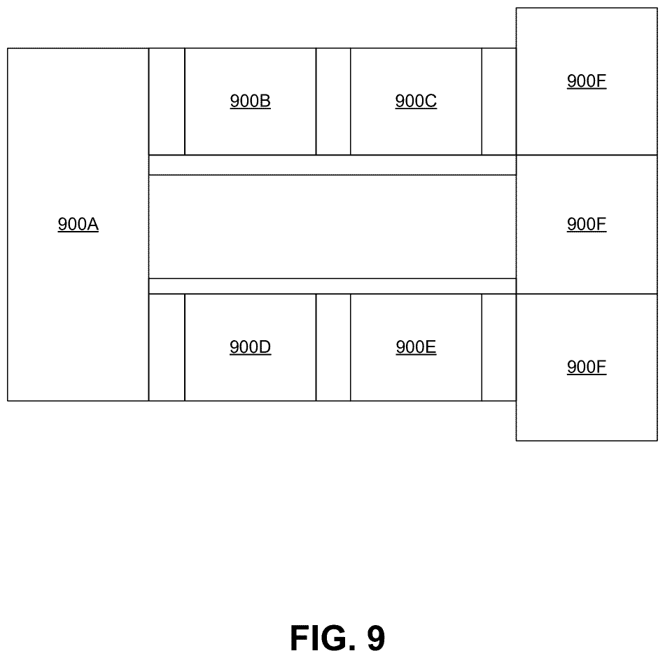

After cleaning, activation modules (900D, 900E), utilizing plasma or chemical processes, can then introduce reactive functional groups or modify the bonding surfaces to prepare them for adhesion. Controlled atmospheric storage modules (900F) may preserve the activated devices in inert conditions, maintaining their cleanliness and stability before downstream processing. These modules work together seamlessly, transporting devices between stages via automated systems that ensure precision and efficiency. The modular activation system provides scalability and adaptability to suit various device configurations, such as individual substrates or dies mounted on ring frames. It also allows customization for specific needs, such as incorporating UV release modules for additional surface preparation. While FIG. 9 demonstrates one exemplary modular configuration, the system design can be tailored with additional modules or alternative transport mechanisms to meet diverse process requirements. This approach streamlines activation steps and enhances the reliability of subsequent hybrid bonding processes.

The disclosed methods for bonding devices by using self-alignment allows the devices to be precisely aligned and bonded in a high volume manufacturing environment. Applying a conventional bonding process like the C4 process (that is optimized for larger bump sizes and pitches) to bond dies with significantly smaller bump sizes and pitches presents several practical challenges. For example, conventional processes relies on established techniques for solder deposition, alignment, and reflow. However, as bump sizes shrink (e.g., to ≤20 microns and pitches decrease to ≤30 microns), precision in alignment becomes increasingly critical, as even minor deviations can lead to misalignment or defects that reduce yield.

Yield refers to the percentage of usable products produced out of the total manufactured units. Higher yield means fewer defective products, which reduces waste and the need for costly rework or scrap, thereby lowering production costs. Increasing yield is vital in a high-volume manufacturing environment because it directly impacts productivity, cost-efficiency, and profitability. Additionally, in competitive industries such as semiconductor manufacturing, higher yields ensure reliable supply to meet market demands and maximize output from expensive fabrication processes. Ultimately, improving yield enhances overall operational efficiency, enabling companies to maintain profitability while scaling production to high volumes.

Although the disclosed processes are especially useful for devices having small bump sizes and pitches (e.g., a bump size less ≤20 microns and bump pitch ≤30 microns), the disclosed processes can be applied without limitation for devices having any size and pitch of bumps. Although the disclosed embodiments describe the bonding of two devices, this is only exemplary. In some embodiments, multiple devices (>2) may be bonded together by hybrid bonding. In some embodiments, multiple devices (e.g., 3 or more devices) may be stacked together and bonded together to form one stacked unit or system. While in some embodiments, multiple pairs of devices may be bonded to each other simultaneously. It will be appreciated that the embodiments of the present disclosure are not limited to the exact construction that has been described above and illustrated in the accompanying drawings and that various modifications and changes may be made without departing from the scope thereof.

What is claimed is:

1. A method of bonding semiconductor devices, comprising:
providing a first device having a first surface and a plurality of first metallic bumps extending from the first surface, wherein a first dielectric layer is disposed on the first surface such that the plurality of first metallic bumps extend through the first dielectric layer to expose end surfaces of the plurality of first metallic bumps;
providing a second device having a second surface and a plurality of second metallic bumps extending from the second surface, wherein a second dielectric layer is disposed on the second surface such that the plurality of second metallic bumps extend through the second dielectric layer to expose end surfaces of the plurality of second metallic bumps;
applying a solder material on the end surfaces of the plurality of first metallic bumps and the plurality of second metallic bumps;
aligning the first device with the second device such that a first bonding surface of the first dielectric layer faces a second bonding surface of the second dielectric layer and at least portions of the solder material on the end surfaces of the plurality of first metallic bumps contact the solder material on the end surfaces of the plurality of second metallic bumps;
after the aligning, heating the first and second devices to reflow the solder material and join the end surfaces of the plurality of first metallic bumps to the end surfaces of the plurality of second metallic bumps using the reflowed solder material; and
after the heating, bonding the first bonding surface of the first dielectric layer to the second bonding surface of the second dielectric layer.

2. The method of claim 1, wherein bonding the first bonding surface to the second bonding surface includes a low-temperature anneal to fuse the first dielectric layer to the second dielectric layer, and wherein the low-temperature anneal includes maintaining the first and second devices at a first temperature between about 100-200° C. for a first time period greater than zero. annealing the first and second devices to fuse together the first dielectric layer to the second dielectric layer.

3. The method of claim 2, wherein the annealing further includes a high-temperature anneal to fuse each bump of the plurality of first metallic bumps to a different bump of the plurality of second metallic bumps, and wherein the high-temperature anneal includes maintaining the first and second devices at a second temperature greater than the first temperature for a second time period equal to or different from the first time period.

4. The method of claim 1, wherein bonding the first bonding surface to the second bonding surface includes using an underfill material to fill a gap between the first bonding surface to the second bonding surface and connect the first dielectric layer to the second dielectric layer through the underfill material.

5. The method of claim 4, wherein the underfill material is a polymer brush.

6. The method of claim 4, wherein the gap between the first bonding surface and the second bonding surface may be less than about 5 microns.

7. The method of claim 1, wherein applying the solder material includes applying a solder material having a phase transition temperature less than about 200° C. on the end surfaces.

8. The method of claim 1, wherein applying the solder material includes applying a solder material having a phase transition temperature less than about 150° C. on the end surfaces.

9. The method of claim 1, wherein applying the solder material includes applying one of indium solder, a lead-tin solder, a bismuth-tin solder, or an indium-tin solder on the end surfaces.

10. The method of claim 1, wherein applying the solder material includes applying the solder material on the end surfaces without applying the solder material on the first and second dielectric layers.

11. The method of claim 1, further including activating the first and the second devices prior to aligning the first device with the second device, wherein the activation includes subjecting the first and second devices to a plasma treatment.

12. The method of claim 1, aligning the first device with the second device includes positioning the first device on the second device such a horizontal offset between a first bump of the plurality of first metallic bumps and a corresponding second bump of the plurality of second metallic bumps is less than or equal to about half a diameter of the first bump or the second bump.

13. The method of claim 1, wherein a diameter of each bump of the plurality of first metallic bumps and the plurality of second metallic bumps is less than or equal to about 20 microns and a pitch of each of the plurality of first metallic bumps and the plurality of second metallic bumps is less than or equal to about 30 microns.

14. A method of bonding semiconductor devices, comprising:
providing a first device having a first surface and a plurality of first copper bumps extending from the first surface, wherein a first dielectric layer is disposed on the first surface such that the plurality of first copper bumps extend through the first dielectric layer and project outwards from a first bonding surface of the first dielectric layer to expose end surfaces of the plurality of first copper bumps;
providing a second device having a second surface and a plurality of second copper bumps extending from the second surface, wherein a second dielectric layer is disposed on the second surface such that the plurality of second copper bumps extend through the second dielectric layer and project outwards from a second bonding surface of the second dielectric layer to expose end surfaces of the plurality of second copper bumps;
applying a solder material on the end surfaces of the plurality of first copper bumps and the plurality of second copper bumps, wherein the solder material is an electrically conductive material having a phase transition temperature less than or equal to about 200° C.;
aligning the first device with the second device such that at least portions of the solder material on the end surfaces of the plurality of first copper bumps contact the solder material on the end surfaces of the plurality of second copper bumps;
after the aligning, reflowing the solder material to join the end surfaces of the plurality of first copper bumps to the end surfaces of the plurality of second copper bumps;
after the reflowing, bonding the first bonding surface of the first dielectric layer to the second bonding surface of the second dielectric layer.

15. The method of claim 14, wherein bonding the first bonding surface to the second bonding surface includes a low-temperature anneal to fuse the first dielectric layer to the second dielectric layer and a high-temperature anneal to fuse each bump of the plurality of first copper bumps to a different bump of the plurality of second copper bumps, and wherein the low-temperature anneal includes maintaining the first and second devices at a first temperature between about 100-200° C. for a first time period greater than zero, and the high-temperature anneal includes maintaining the first and second devices at a second temperature greater than the first temperature for a second time period equal to or different from the first time period.

16. The method of claim 14, wherein bonding the first bonding surface to the second bonding surface includes using an underfill material to fill a gap between the first bonding surface to the second bonding surface and connect the first dielectric layer to the second dielectric layer through the underfill material.

17. The method of claim 16, wherein the underfill material is a polymer brush.

18. The method of claim 16, wherein the gap between the first bonding surface and the second bonding surface is less than about 5 microns.

19. The method of claim 14, wherein a diameter of each bump of the plurality of first copper bumps and the plurality of second copper pumps is less than or equal to about 20 microns and a pitch of each of the plurality of first copper bumps and the plurality of second copper pumps is less than or equal to about 30 microns.

20. The method of claim 14, aligning the first device with the second device includes positioning the first device on the second device such a horizontal offset between a first bump of the plurality of first copper bumps and a corresponding second bump of the plurality of second copper bumps is less than or equal to about half a diameter of the first bump or the second bump.

21. A method of bonding semiconductor devices, comprising:
providing a first device having a first surface and a plurality of first metallic bumps extending from the first surface, wherein a first dielectric layer is disposed on the first surface such that the plurality of first metallic bumps extend through the first dielectric layer to expose end surfaces of the plurality of first metallic bumps;
providing a second device having a second surface and a plurality of second metallic bumps extending from the second surface, wherein a second dielectric layer is disposed on the second surface such that the plurality of second metallic bumps extend through the second dielectric layer to expose end surfaces of the plurality of second metallic bumps;
applying one or more self-assembled monolayers or one or more layers of polymer brushes on a first surface of the first dielectric layer and a second surface of the second dielectric layer;
aligning the first device with the second device to contact the one or more self-assembled monolayers or one or more layers of polymer brushes on the first surface of the first dielectric layer to the one or more self-assembled monolayers or one or more layers of polymer brushes on the second surface of the second dielectric layer such that at least a portion the end surface of a first bump of the plurality of first metallic bumps overlies the end surface of a second bump of the plurality of second metallic bumps; and
after the aligning, annealing the first and second devices to join the first dielectric layer to the second dielectric layer and join each bump of the plurality of first metallic bumps to a different bump of the plurality of second metallic bumps.

22. The method of claim 21, wherein the annealing includes applying a pressure to press the first and second devices together.

23. The method of claim 21, wherein applying the one or more self-assembled monolayers or one or more layers of polymer brushes includes exposing the first surface and the second surface to a solution containing molecules of the self-assembled monolayers.

24. The method of claim 21, aligning the first device with the second device includes positioning the first device on the second device such a horizontal offset between the first bump and the second bump is less than or equal to about half a diameter of the first bump or the second bump.

25. The method of claim 21, wherein a diameter of each bump of the plurality of first metallic bumps and the plurality of second metallic bumps is less than or equal to about 20 microns and a pitch of each of the plurality of first metallic bumps and the plurality of second metallic bumps is less than or equal to about 30 microns.
